(19) United States
(12) Patent Application Publication
(10) Pub. No.: US 2019/0095299 A1
(43) Pub. Date: Mar. 28, 2019

(54) STORAGE SYSTEM WITH MACHINE LEARNING MECHANISM AND METHOD OF OPERATION THEREOF

(71) Applicant: CNEX LABS, Inc., San Jose, CA (US)

(72) Inventors: Yi Liu, San Diego, CA (US); Xiaojie Zhang, Saratoga, CA (US); Alan Armstrong, Los Altos, CA (US)

(21) Appl. No.: 15/718,795

(22) Filed: Sep. 28, 2017

(51) Int. Cl. G06F 11/22; G06N 99/00; G11C 29/44

(52) U.S. Cl. CPC G06F 11/2257; G11C 29/44; G06N 99/005

(57) ABSTRACT

A storage system includes: a control processor, configured to: read user data, calculate error statistics from the user data, and operate a machine learning mechanism configured to identify a bad sector based on the error statistics; and a non-volatile memory array, coupled to the control processor, configured to store the user data; and wherein the control processor is further configured to map out the bad sector, based on the machine learning mechanism, and move the user data to a target sector for enhancing performance of the non-volatile memory array.

### TECHNICAL FIELD

An embodiment of the present invention relates generally to a storage system, and more particularly to a system for data reliability using machine learning.

### BACKGROUND

Nonvolatile memory, such as NAND flash, has driven massive increases in capacity and verification processes to support intelligent devices. In order to reduce the cost per gigabyte nonvolatile memories, these devices have become denser by packing more data in the same silicon area, by scaling the size of the flash cells, adding three dimensional arrays of storage cells, and storing more bits in each of them, but the changes in cell-size and storage cell configuration has come at the cost of read back reliability. Nonvolatile memory cells gradually wear out during their lifetime, resulting in a decreasing of the read back reliability. A mechanism must be found to provide the desired data reliability while minimizing the recovery processes and error correction techniques.

Thus, a need still remains for a storage system with machine learning mechanism to provide improved data reliability and minimize recovery processes. In view of the ever-increasing commercial competitive pressures, along with growing consumer expectations and the diminishing opportunities for meaningful product differentiation in the marketplace, it is increasingly critical that answers be found to these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### SUMMARY

An embodiment of the present invention provides an apparatus, including a control processor, configured to: read user data, calculate error statistics from the user data, and operate a machine learning mechanism configured to identify a bad sector based on the error statistics; and a non-volatile memory array, coupled to the control processor, configured to store the user data; and wherein the control processor is further configured to map out the bad sector, based on the machine learning mechanism, and move the user data to a target sector for enhancing performance of the non-volatile memory array.

An embodiment of the present invention provides a method including: reading user data from a non-volatile memory array; calculating error statistics from the user data; operating a machine learning mechanism with the error statistics; identifying a bad sector by the machine learning mechanism; and mapping out the bad sector including moving the user data to a target sector for enhancing performance of the non-volatile memory array.

An embodiment of the present invention provides a non-transitory computer readable medium including: reading user data from a non-volatile memory array; calculating error statistics for the user data; operating a machine learning mechanism with the error statistics; identifying a bad sector by the machine learning mechanism; and mapping out the bad sector including moving the user data to a target sector for enhancing performance of the non-volatile memory array.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is a storage system with machine learning mechanism in an embodiment of the present invention.

FIG. 2 depicts an architectural view of a support vector machine in an embodiment of the present invention.

FIG. 3 is an architectural view of the non-volatile memory array in an embodiment.

FIG. 4 is a performance graph of the frame error rate versus the P/E cycle count with the support vector machine controlling the bad sectors.

FIG. 5 is an operational flow diagram of the storage system with machine learning mechanism in an embodiment of the present invention.

FIG. 6 is a flow chart of a method of operation of a storage system in an embodiment of the present invention.

### DETAILED DESCRIPTION

The following embodiments are described in sufficient detail to enable those skilled in the art to make and use the invention. It is to be understood that other embodiments would be evident based on the present disclosure, and that system, process, or mechanical changes may be made without departing from the scope of an embodiment of the present invention.

In the following description, numerous specific details are given to provide a thorough understanding of the invention. However, it will be apparent that the invention may be practiced without these specific details. In order to avoid obscuring an embodiment of the present invention, some well-known circuits, system configurations, and process steps are not disclosed in detail.

The drawings showing embodiments of the system are semi-diagrammatic, and not to scale and, particularly, some of the dimensions are for the clarity of presentation and are shown exaggerated in the drawing figures. Similarly, although the views in the drawings for ease of description generally show similar orientations, this depiction in the figures is arbitrary for the most part. Generally, the invention can be operated in any orientation.

The term “module” referred to herein can include hardware or hardware supported by software in an embodiment of the present invention in accordance with the context in which the term is used. For example, the software can be machine code, firmware, embedded code, and application software. Also for example, the hardware can be circuitry, processor, computer, integrated circuit, integrated circuit cores, application specific integrated circuit (ASIC), passive devices, or a combination thereof.

As an example, one method to reduce the time spent in error recovery is to apply a machine learning mechanism to predict the failure of a storage sector which could be a read/write unit sector, a physical page, a word line, or a physical block and map it out of the usable storage before the errors become unrecoverable. In some cases, the storage sector that is showing a degradation in read reliability can be preserved by the use of a more powerful error correction strategy. In either case the storage sector can be mapped out and replaced by a fresh storage sector from the non-volatile memory array prior to the data within the storage sector being detected as uncorrectable.

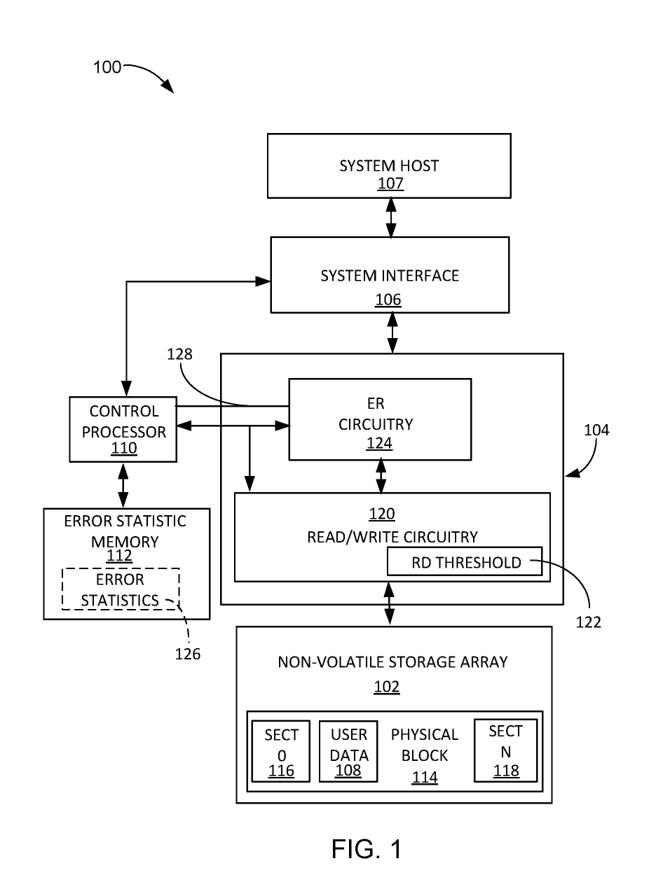

Referring now to FIG. 1, therein is shown a functional block diagram of a storage system 100 with machine learning mechanism in an embodiment of the present invention. The functional block diagram of the storage system 100 depicts a non-volatile memory array 102 coupled to a read/write channel 104. A system interface 106 can transfer user data 108 through the read/write channel 104 for storage to and retrieval from the non-volatile memory array 102. A control processor 110 can be coupled to the system interface 106, the read channel 104, and an error statistic memory 112. The error statistic memory 112 can be a volatile memory array, such as a matrix of interconnected volatile memory integrated circuits including dynamic random access memory (DRAM), static random access memory (SRAM), register files, a non-volatile memory, or a combination thereof, coupled to the control processor 110.

The system interface 106 can be supported by the control processor 110. The control processor 110 can be implemented with hardware circuitry in a number of different manners. For example, the control processor 110 can be a processor, an application specific integrated circuit (ASIC), an embedded processor, a microprocessor, a hardware control logic, a hardware finite state machine (FSM), a digital signal processor (DSP), or a combination thereof. The control processor 110 can coordinate the operation of the storage system 100. The system interface 106 can execute the movement of the user data 108 into and out of the storage system 100. The system interface 106 can be implemented as a hardware control logic, a hardware finite state machine (FSM), or a programmable bus controller, that can provide data transport between the non-volatile memory array 102 and a system host 107. The system host 107 can be a computer, a processor, a processor core, a device controller, or a combination thereof configured to generate, store, and retrieve the user data 108. The host system 107 can be directly coupled to the system interface 106, or it can be attached through a local bus, a local area network (LAN), or wide area network (WAN).

The non-volatile memory array 102 can be a matrix of interconnected non-volatile memory integrated circuits, such as NAND flash array of single level cells (SLC) or multi-level cells (MLC) or another non-volatile memory technology. The cells in the non-volatile memory array 102 are organized into a plurality of physical blocks 114. Each of the physical blocks 114 can contain data sectors from sector 0 116 through sector N 118.

The read/write channel 104 can be a hardware structure that can be supported by software, to encode and decode the user data 108 for storage in the non-volatile memory array 102. A read/write circuitry 120 can manage the writing to the sector 0 116 through sector N 118. During the reading of the user data 108, the read/write circuitry 120 can manipulate a read threshold 122 in order to adjust for errors detected by an error recovery (ER) circuitry 124. The ER circuitry 124 can provide statistics on the error processing on each of the sector 0 116 through sector N 118.

The control processor 110 can monitor error statistics 126 from the ER circuitry 124 and maintain the error statistics 126 in the error statistic memory 112. The ER circuitry 124 can provide a 2-stage correction mechanism. The first stage is a detection of an uncorrectable error read from the non-volatile memory array 102. The ER circuitry 124 can assert an uncorrectable error trigger 128 to alert the control processor 110 that the uncorrectable data error has occurred and the second stage of the error correction mechanism must be activated. The second stage of the error correction mechanism can include threshold modifications, re-read of the user data 108, error correction soft processes, or a combination thereof.

The error statistics 126 can be stored for each of the sector 0 116 through sector N 118. The error statistics 126 can be dynamically adjusted by adding current information from the ER circuitry 124 to a past error statistics 126. The control processor 110 can predict the future behavior, of the sector 0 116 through sector N 118, based on a machine learning mechanism processing of the error statistics 126, such as the bit error count, in order to map out bad sectors before they exceed the capacity of error correcting code in the ER circuitry 124. When the control processor 110 has identified a potential failing sector among the sector 0 116 through sector N 118, a stronger error correction code can be invoked in the ER circuitry 124 or the control processor 110 can map out the potential failing sector.

The control processor 110 can manage the operation of the read/write channel 104 including performing calculations, optimizing a read threshold 122, and execution of interface commands delivered from the host system 107. The ER circuitry 120 can provide the error statistics 126 when reading the user data 108 that has ECC correctable errors. The ER circuitry 120 can be a hardware structure used to encode intended or targeted data for providing error protection, error detection, error correction, redundancy, or a combination thereof.

For illustrative purposes, the storage system 100 will be described as utilizing the machine learning mechanism in storing and accessing information with NAND flash memory. However, it is understood that the storage system 100 can utilize the machine learning mechanism with other types of memory, such as resistive non-volatile memory, other types of flash or non-volatile memory, or a combination thereof.

It is understood that the embodiment discussed above is used to describe the invention and other embodiments are possible. Another possible embodiment can integrate the control processor 110, the read/write channel 104, the system interface 106, the non-volatile memory array 102, or a combination thereof into a single circuit.

It has been discovered that the control processor 110 can proactively map out any of the sector 0 116 through sector N 118 in the physical block 114. This can allow the ER circuitry 120 to calculate the error statistics 126 for further monitoring the read reliability of the sector 0 116 through sector N 118.

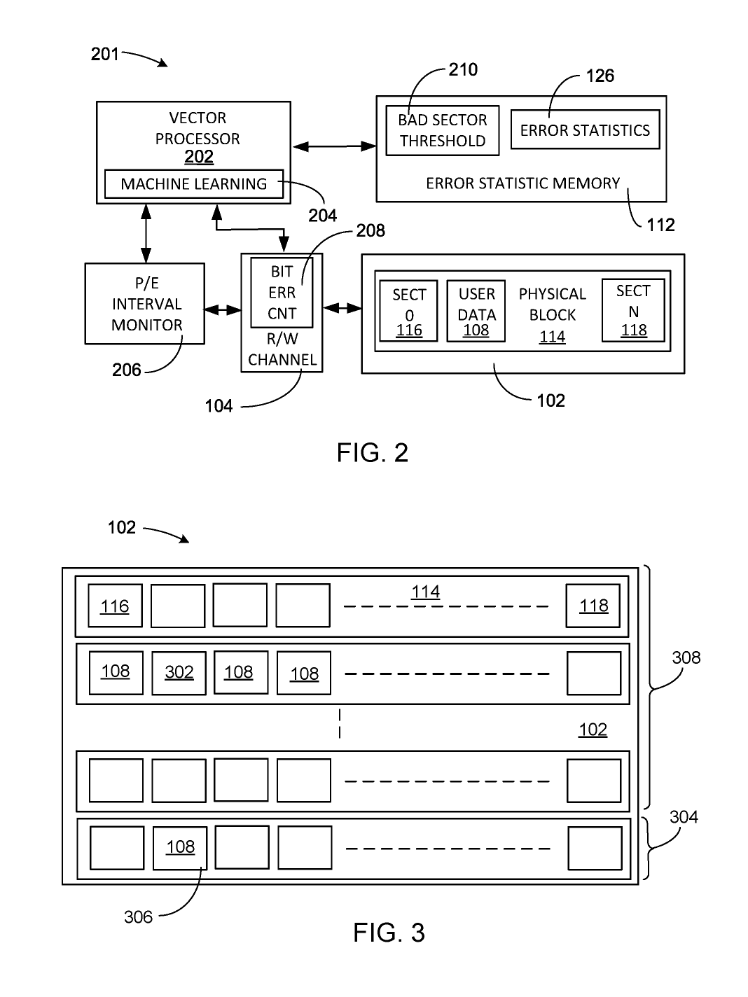

Referring now to FIG. 2, therein is shown an architectural view of a support vector machine (SVM) 201 in an embodiment of the present invention. The architectural view of the support vector machine (SVM) 201 depicts a vector processor 202 coupled to the read/write channel 104. The vector processor 202 can be a specific math co-processor, a hardware math execution array, a processor core running software, or the control processor 110 running a specific software. The vector processor 202 can include a machine learning mechanism 204 for monitoring the error statistics 126 and maintaining the read reliability of the sector 0 116 through sector N 118 in the physical block 114. An initial state of the machine learning mechanism 204 can be derived from test devices.

The machine learning mechanism 204 is further refined by monitoring the error statistics 126 during operation of the non-volatile memory array 102 as part of a training period that can be triggered at the initial assertion of the uncorrectable error trigger 128 of FIG. 1. During the operation of the storage system 100, the support vector machine (SVM) 201 can refine an initial state by enhancing the control of the the sector 0 116 through sector N 118 based on the error statistic 126 of the non-volatile storage array 102 when the assertion of the uncorrectable error trigger 128. The assertion of the uncorrectable error trigger 128 triggers the machine learning session of the support vector machine (SVM) 201. In some error conditions, the control processor 110 can restore the initial state of the machine learning mechanism as part of the error recovery process.

A program/erase (P/E) interval monitor 206 can monitor the activity of the ER circuitry 124 during the correction of the user data 108. The P/E interval monitor 206 can be a hardware function or a software running on the control processor 110 configured to tabulate a bit error count 208 for each of the sector 0 116 through sector N 118 throughout the non-volatile memory array 102. The P/E interval monitor 206 can pass the bit error count 208 information to the machine learning mechanism 204 of the vector processor 202 at a selected interval of the program/erase cycles of each of the sector 0 116 through sector N 118. The machine learning mechanism 204 can consider the total number of bit errors (Tₘ) of a sector during the read back operation at P/E cycles counts Tₘ by Nₘ. The vector processor 202 applies the machine learning inference mechanism with error statistics 126 and the measured error count 208 to compute a bad sector identification value. If the computed identification value exceeds a predefined threshold, the vector processor 202 can declare that this sector is bad.

By evaluating the bit error count 208 N₁, N₂, . . . , Nₘ at P/E cycle counts before T_{N} (T₁, T₂, . . . , Tₘ<T_{N}), the vector processor 202 can predict whether any of the sector 0 116 through sector N 118 will be bad at T_{N}. Once the vector processor 202 can identify a bad sector, the control processor 110 can either map out the bad sector or use strong error correction code (ECC) to protect any of the sector 0 116 through sector N 118. The machine learning mechanism 204 can monitor the read reliability of the sector 0 116 through sector N 118, including different P/E cycles intervals and data size.

The machine learning mechanism 204 can correctly predict the bad sectors in the physical block 114 before they can reach an uncorrectable data state. First, the initial error statistics can be collected from test devices. With a given sector i, the machine learning mechanism 204 can define a vector xᵢ={N₁, N₂, . . . , Nₘ} to be a point in m dimension real number space [symbol] ^{m} with the error statistics 126 and label yᵢ=1 if this sector will be bad or yᵢ=−1 if this sector will be good in certain furture P/E cycle count. The machine learning mechanism 204, such as neural network and linear classifier, can be trained using xᵢ and yᵢ. For example, for a support vector machine, vector w={W₁, W₂, . . . , Wₘ} and scalar b is trained by minimizing ∥w∥₂²+Σ C(yᵢ)max{0,1−yᵢ (wxᵢ−b)}. Where ∥w∥₂² is called the regularization loss and Σ C(yᵢ)max{0,1−yᵢ (wxᵢ−b)} is called the hinge loss. The regularization loss can represent the penalty of overfitting. The hinge loss can represent the penalty of misclassifying the data. Where ∥w∥₂² is called the regularization loss and Σ C(yᵢ)max{0,1−yᵢ (wxᵢ−b)} is called the hinge loss. The regularization loss can represent the penalty of overfitting. The hinge loss can represent the penalty of misclassifying the data.

After a training process, the machine learning mechanism 204 can be used on other flash memory devices. It uses xᵢ as input to predict yᵢ by calculating zᵢ. For example, for a trained support vector machine, a bad sector indicator zᵢ can be calculated by:

zᵢ₌wxᵢ−b Equation (1)

By the machine learning mechanism 204 performing the calculation, if zᵢ>0, the sector will be labeled as bad sector and if zᵢ<0, the sector will be labeled as good sector.

The machine learning mechanism 204 can include non-linear components, also called a kernel trick, can be used to modify the machine learning mechanism 204. The machine learning mechanism 204 can include kernels, such as radial basis function (RBF) and polynomial kernels, used to increase the performance of the vector processor 202. For example, the machine learning mechanism 204 can add two non-linear features to the support vector machine 201.

EN1=|Nₘ−Nₘ₋₁| Equation (2)

and

EN2=|Nₘ₋₁−Nₘ₋₂| Equation (3)

The combination of EN1 and EN2 can provide a non-linear component of the error statistics 126 for the sector 0 116 through sector N 118. The application of the EN1, EN2, or the combination thereof can enhance the efficiency of the support vector machine (SVM) 201. The quality of the support vector machine (SVM) 201 can be measured by accuracy and recall. The Accuracy can be defined as:

$$Accuracy = \frac{number of misclassification}{number of samples} \qquad Equation ( 4 )$$

The Recall can be defined as:

$$Recall = \frac{number of bad sectors correctly detected}{number of bad sectors} \qquad Equation ( 5 )$$

By designing the machine learning mechanism 204 with the Recall much more significant than the Accuracy, the support vector machine (SVM) 201 can map out bad sectors prior to detecting any uncorrectable errors. In the application of the support vector machine (SVM) 201, a limit in the percentage of the sector 0 116 through sector N 118 that can be mapped out.

It is understood that the any of the sector 0 116 through sector N 118 that is mapped out can be immediately replaced by target sectors in the non-volatile memory array 102. By performing the map out process on the non-volatile memory array 102 the performance of the storage system 100 of FIG. 1 can be enhanced because the read/write channel 104 does not have to perform the additional reads to address the uncorrectable errors that require multiple reads of the same sector using different values of the read threshold 122 of FIG. 1 in an attempt to correctly read the user data 108.

Referring now to FIG. 3, therein is shown an architectural view of the non-volatile memory array 102 in an embodiment. The architectural view of the non-volatile memory array 102 can depict a number of the physical block 114, each having the sector 0 116 through sector N 118. As an example, a bad sector 302 can be identified by the support vector machine (SVM) 201 of FIG. 2. The non-volatile memory array 102 can include a reserve capacity 304, which can include one or more of the physical block 114. A target sector 306 can be assigned to replace the bad sector 302 when it is mapped out.

Further for example, the user data 108 that was initially written to the bad sector 302 can be moved to the target sector 306 by the support vector machine (SVM) 201 with no involvement of the system host 107 of FIG. 1 as part of a garbage collection (GC) background process. The target sector 306 can be a portion of the reserve capacity 304, a portion of an active capacity 308, or a combination thereof. The active capacity 308 is defined as the working capacity of the non-volatile memory array 102.

It has been discovered that the support vector machine (SVM) 201 can predict the imminent failure of the bad sector 302 and move the user data 108 to the target sector 306 before an uncorrectable error is detected. The support vector machine (SVM) 201 can have a preset limit on the number of the target sector 306 that can be utilized without notifying the host system, Upon notification of reaching the limit, the host system can increase the percentage of the target sector 306 allowed before an additional notification of an uncorrectable error is issued. During the utilization of the target sector 306, no uncorrectable errors will be reported because the support vector machine (SVM) 201 will map out the bad sector 302 and move the user data 108 to the target sector 306 before the uncorrectable error can occur.

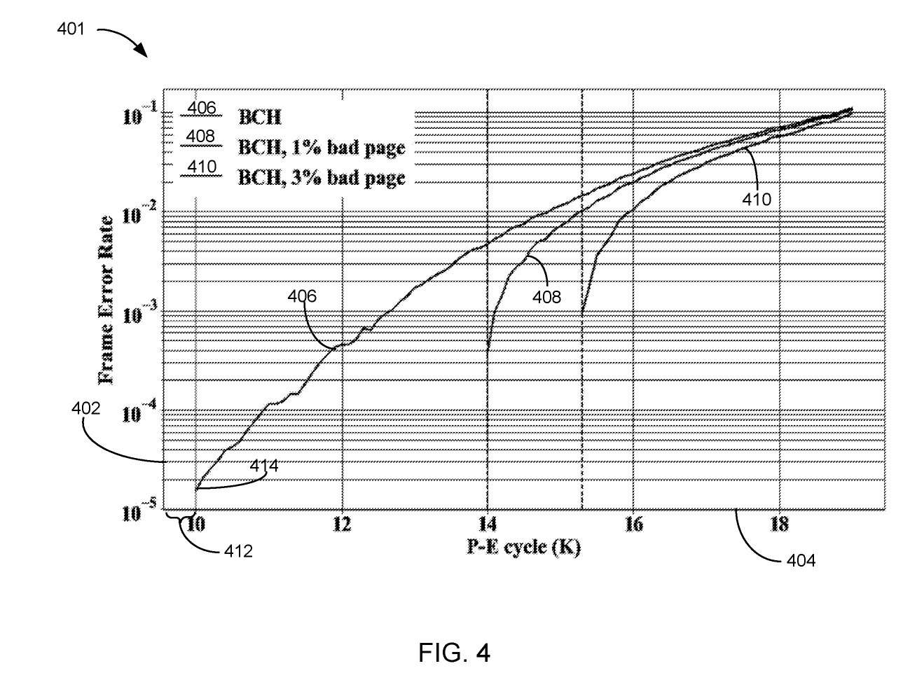

Referring now to FIG. 4, therein is shown a performance graph 401 of the frame error rate versus the P/E cycle count with the support vector machine controlling the bad sectors. The performance graph 401 depicts a vertical axis with the frame error rate 402. A horizontal axis depicting the number of program/erase (P/E) cycles 404 performed on each of the sector 0 116 of FIG. 1 through sector N 118 of FIG. 1.

An unassisted curve 406 can show the performance of the non-volatile memory array 102 of FIG. 1 using only the Bose-Chaudhuri-Hocquengham (BCH) code for error correction. The region above the unassisted curve 406 represents uncorrectable errors and the region below the unassisted curve 406 represents a correctable error region. It is evident that there are uncorrectable errors detected with a frame error rate of 9.4E-4 starting at 10,000 P/E cycles.

The application of the support vector machine (SVM) 201 being allowed to map out 1% of bad sectors 302 of FIG. 3 replaced by the target sector 306 of FIG. 3 can provide a one percent curve 408 showing no uncorrectable errors up until 14,000 P/E cycles and a frame error rate of 8.5E-3 after no target sectors left. The performance of the non-volatile memory array 102 is significantly increased because the read/write channel 104 of FIG. 1 is not required to perform additional reads of the error data in order to attempt correction. This enhancement can translate into significant performance benefit to the host system (not shown).

In an example of operational performance, upon being notified of a retry corrected data, the host system can authorize an additional percentage of the target sector 306 be used to map out the bad sector 302. By increasing the allowable percentage of the target sector 306 from 1% to 3%, a three percent curve 410 shown that there are no uncorrectable errors up to 15,300 P/E cycles and a frame error rate of 1.5E-3 after no target sectors left. This again provides significant performance improvement beyond both the unassisted curve 406 and the one percent curve 408.

The machine learning mechanism 204 can be refined to process the error statistics 126 of FIG. 1 for predicting the bad sector threshold 210 during a training period 412. The training period 412 can be triggered by the first uncorrectable data error 414 is detected, including the assertion of the unconditional error trigger 128 of FIG. 1, when reading the user data 108. When the first possible bad sector is detected and the uncorrectable error trigger 128 is asserted, the refine training period is started, and the support vector machine (SVM) 201 begins to improve the bad sector prediction mechanism.

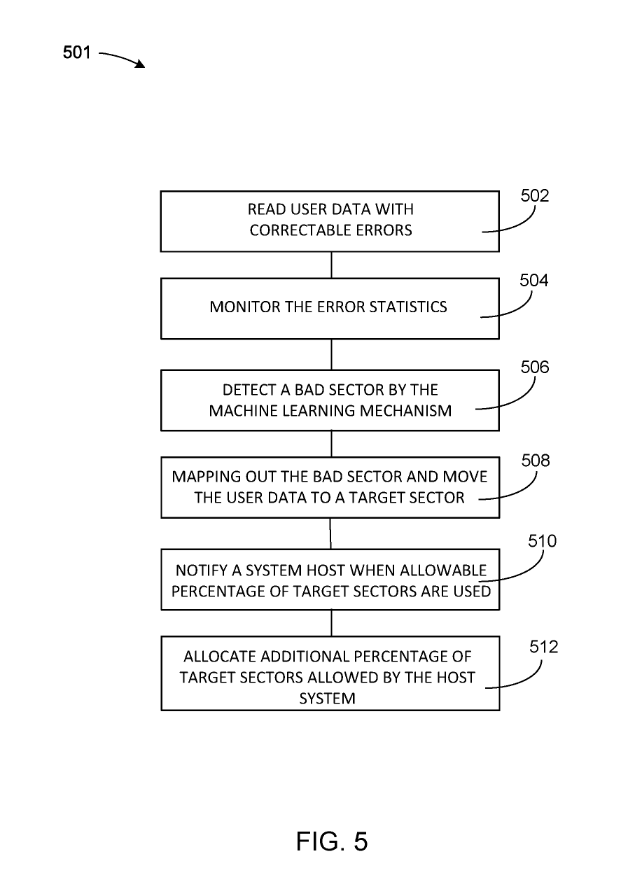

Referring now to FIG. 5, therein is shown an operational flow diagram 501 of the storage system 100 with machine learning mechanism in an embodiment of the present invention. It is understood that the functions described in this application can be implemented as instructions stored on a non-transitory computer readable medium to be executed by a host processor, not shown, the control processor unit 110 of FIG. 1, a math co-processor, a processor core, or a combination thereof.

The non-transitory computer readable medium can include compact disk (CD), digital video disk (DVD), or universal serial bus (USB) flash memory devices. The non-transitory computer readable medium can be integrated as a part of a host system not shown or installed as non-volatile memory array 102 of the storage system 100.

The non-transitory computer readable medium can include instructions required to perform the operations of “reading user data with correctable errors” 502. The correctable errors can be corrected by processes, such as parity correction, ECC processing, low density parity check (LDPC), or other error correction processes. The flow includes “monitoring the error statistics” 504. The ER circuitry 124 of FIG. 1 can correct the bit errors in the user data 108 of FIG. 1 and pass the bit error count 208 of FIG. 2 to the machine learning mechanism 204 of FIG. 2 for evaluation.

The flow can include “detecting a bad sector by the machine learning mechanism” 506, in which the support vector machine (SVM) 201 of FIG. 2 can use the error statistics to calculate zᵢ. When positive zᵢ is observed, this sector will be label as bad sectors. The bad sector 302 of FIG. 3 can be detected before the bit error count 208 of FIG. 2 in the user data 108 can become uncorrectable errors.

The flow includes “mapping out the bad sector and move the user data to a target sector” 508, as shown in FIG. 3, the bad sector 302 can be mapped out and the user data 108 of FIG. 1 can be moved to the target sector 306 of FIG. 3.

The flow includes “notify a system host when allowable percentage of target sectors are used” 510. The control processor 110 of FIG. 1 can send an exception message to the system host 107 of FIG. 1 when the allowable percentage of the target sectors 306 have been used. This notification can prevent the utilization of all of the target sectors 306, which can result in uncorrectable errors presented to the system host 107 of FIG. 1.

The flow can include “allocate additional percentage of target sectors allowed by the host system” 512. It is understood that the control processor unit 110 can adjust the allowed percentage of the target sectors 306 that can be used by the support vector machine (SVM) 201. The system host 107 or the control processor 110 can authorize the use of additional percentage of the target sectors 306 in order to maintain the peak performance of the non-volatile memory array 102 and the storage system 100.

It has been discovered that the storage system 100 can increase performance when accessing the user data 108. The application of the machine learning mechanism 204 of FIG. 2 can enhance the performance of the non-volatile memory array 102 by preventing the occurrence of uncorrectable errors due to wear of the cells in the sector 0 116 of FIG. 1 through sector N 118 of FIG. 1. It is understood that the support vector machine (SVM) 201 is aware of the garbage collection process and the wear leveling process and can be used independently or in conjunction with them.

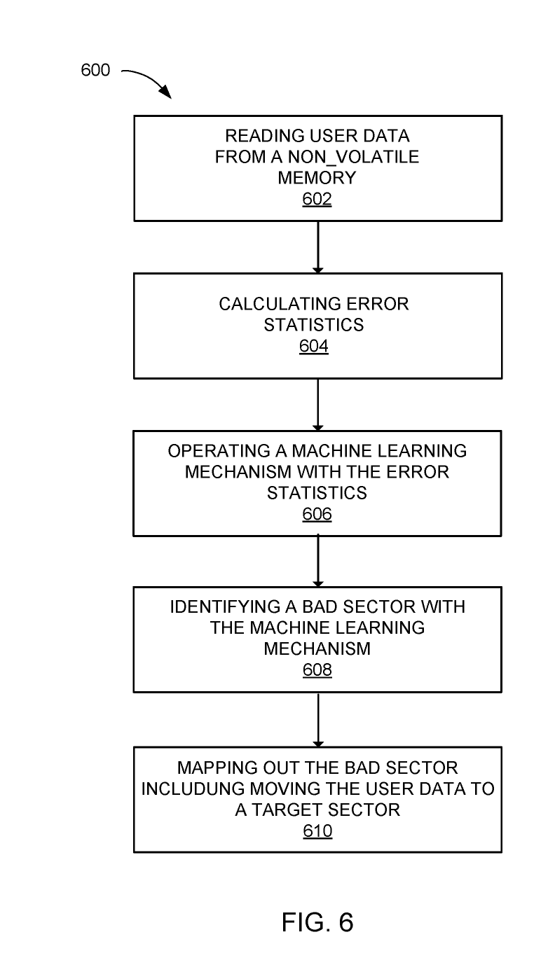

Referring now to FIG. 6, therein is shown a flow chart of a method 600 of operation of a storage system 100 in an embodiment of the present invention. The method 600 includes: reading user data from a non-volatile memory in a block 602; calculating error statistics from the user data in a block 604; operating a machine learning mechanism with the error statistics in a block 606; identifying a bad sector by the machine learning mechanism in a block 608; and mapping out the bad sector including moving the user data to a target sector for enhancing performance of the non-volatile memory in a block 610.

The resulting method, process, apparatus, device, product, and/or system is straightforward, cost-effective, uncomplicated, highly versatile, accurate, sensitive, and effective, and can be implemented by adapting known components for ready, efficient, and economical manufacturing, application, and utilization. Another important aspect of an embodiment of the present invention is that it valuably supports and services the historical trend of reducing costs, simplifying systems, and increasing performance.

These and other valuable aspects of an embodiment of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters set forth herein or shown in the accompanying drawings are to be interpreted in an illustrative and non-limiting sense.

What is claimed is:

1. A storage system comprising:
a control processor, configured to:
read user data,
calculate error statistics from the user data, and
operate a machine learning mechanism configured to identify a bad sector based on the error statistics; and
a non-volatile memory array, coupled to the control processor, configured to store the user data; and
wherein the control processor is further configured to map out the bad sector, based on the machine learning mechanism, and move the user data to a target sector for enhancing performance of the non-volatile memory array.

2. The system as claimed in claim 1 wherein the control processor is further configured to monitor the error statistics for each of the sector 0 through sector N.

3. The system as claimed in claim 1 wherein the control processor is further configured to refine the machine learning mechanism for determining a bad sector by monitoring the error statistics.

4. The system as claimed in claim 1 wherein the control processor is further configured to operate a program/erase (P/E) interval monitor to pass the error statistics to the machine learning mechanism at selected intervals of the P/E cycle.

5. The system as claimed in claim 1 wherein the control processor is further configured to calculate a non-linear component of the error statistics with past error statistics.

6. The system as claimed in claim 1 wherein the control processor is further configured to operate the machine learning mechanism by calculating a bad sector indicator.

7. The system as claimed in claim 1 wherein the control processor is configured to identify the bad sector includes comparing the error statistics to a bad sector threshold.

8. The system as claimed in claim 1 wherein the control processor is further configured to predict the bad sector includes calculating a non-linear component of the error statistic.

9. The system as claimed in claim 1 wherein the control processor is further configured to refine the machine learning mechanism when an uncorrectable error trigger is activated.

10. The system as claimed in claim 1 wherein the control processor is further configured to restore the machine learning mechanism to an initial state.

11. A method of operation of a storage system comprising:
reading user data from a non-volatile memory array;
calculating error statistics from the user data;
operating a machine learning mechanism with the error statistics;
identifying a bad sector by the machine learning mechanism; and
mapping out the bad sector including moving the user data to a target sector for enhancing performance of the non-volatile memory array.

12. The method as claimed in claim 11 wherein reading the user data includes monitoring the bit error count for each of the sector 0 through sector N.

13. The method as claimed in claim 11 further comprising refining the machine learning mechanism for determining a bad sector by monitoring the bit error count.

14. The method as claimed in claim 11 further comprising passing the error statistics to the machine learning mechanism at selected intervals of the P/E cycle.

15. The method as claimed in claim 11 further comprising calculating a non-linear component of the error statistics with past error statistics.

16. The method as claimed in claim 11 wherein operating the machine learning mechanism with the error statistics includes calculating a bad sector indicator.

17. The method as claimed in claim 11 wherein identifying the bad sector includes comparing the bit error count to a bad sector threshold.

18. The method as claimed in claim 11 further comprising calculating a non-linear component of the error statistic.

19. The method as claimed in claim 11 further comprising refining the machine learning mechanism when an uncorrectable error trigger is activated.

20. The method as claimed in claim 11 further comprising restoring the machine learning mechanism to an initial state.

21. A non-transitory computer readable medium including instructions for execution, the medium comprising:
reading user data from a non-volatile memory array;
calculating error statistics for the user data;
operating a machine learning mechanism with the error statistics;
identifying a bad sector by the machine learning mechanism; and
mapping out the bad sector including moving the user data to a target sector for enhancing performance of the non-volatile memory array.

22. The medium as claimed in claim 21 wherein reading the user data includes monitoring the bit error count for each of the sector 0 through sector N.

23. The medium as claimed in claim 21 further comprising refining the machine learning mechanism for determining a bad sector by monitoring the bit error count.

24. The medium as claimed in claim 21 further comprising passing the error statistics to the machine learning mechanism at selected intervals of the P/E cycle.

25. The medium as claimed in claim 21 further comprising calculating a non-linear component of the error statistics with past error statistics.

26. The medium as claimed in claim 21 wherein operating the machine learning mechanism with the error statistics includes calculating a bad sector indicator.

27. The medium as claimed in claim 21 wherein identifying the bad sector includes comparing the bit error count to a bad sector threshold.

28. The medium as claimed in claim 21 further comprising calculating a non-linear component of the error statistic.

29. The medium as claimed in claim 21 further comprising refining the machine learning mechanism when an uncorrectable error trigger is activated.

30. The medium as claimed in claim 21 further comprising restoring the machine learning mechanism to an initial state.
